(19) United States
(12) Patent Application Publication
(10) Pub. No.: US 2009/0308316 A1
(43) Pub. Date: Dec. 17, 2009

(54) Transfer apparatus and organic deposition device with the same

(76) Inventor: Jae-Wan Park, Suwon-si (KR)

Correspondence Address: ROBERT E. BUSHNELL & LAW FIRM, 2029 K STREET NW, SUITE 600, WASHINGTON, DC, 20006-1004, US

(21) Appl. No.: 12/318,247

(22) Filed: Dec. 23, 2008

(30) Foreign Application Priority Data
Jun. 16, 2008 (KR) 10-2008-0056254

(51) Int. Cl. C23C 16/00

(52) U.S. Cl. 118/719

(57) ABSTRACT

A transfer apparatus and an organic deposition device have the same capability of increasing stability under high-temperature and high-vacuum environments. The organic deposition device includes: a vacuum chamber; a stage installed in the vacuum chamber and having a substrate seated thereon; a deposition source for evaporating an organic toward the substrate; a process utility line coupled to the deposition source and drawn out to the exterior of the vacuum chamber; and a transfer apparatus for moving the deposition source in a direction parallel to a direction of the substrate, and having the process utility line installed therein.

### CLAIM OF PRIORITY

This application makes reference to, incorporates the same herein, and claims all benefits accruing under 35 U.S.C. §119 from an application for TransferApparatus and Organic Deposition Device with the Same, earlier filed in the Korean Intellectual Property Office on the 16^{th} of Jun. 2008 and there duly assigned Serial No. 10-2008-0056254.

### BACKGROUND OF THE INVENTION

1. Technical Field

The present invention relates to a transfer apparatus and an organic deposition device with the capability of increasing stability under high-temperature and high-vacuum environments.

2. Related Art

Recently, technology for forming a thin film of an organic compound, an organic metal compound, and a functional polymer has become increasingly important. The technology for forming the thin film is used for various materials, such as a conductive material, an optoelectronic material, an electro-luminescence material, etc., in addition to being used as an insulating layer material of a semiconductor element.

With respect to previously developed thin film forming methods, there are various methods such as a vacuum deposition method, a sputtering method, an ion-beam deposition method, a pulsed-laser deposition method, a molecular beam epitaxy (MBE) method, a chemical vapor deposition (CVD) method, a spin-coater method, a plating method, a sol-gel coating method, etc.

The vacuum deposition method is technology wherein a thermal evaporation source is installed on a lower part of a vacuum chamber and a substrate for film formation is installed on an upper part of the thermal evaporation source so as to form a thin film on the substrate. An organic thin film forming apparatus using the vacuum deposition method includes a vacuum exhaust system coupled to the vacuum chamber. The apparatus is constituted to form the thin film by maintaining the vacuum chamber in a constant vacuum state using such a vacuum exhaust system, and then evaporating at least one organic thin film material in the thermal evaporation source disposed on a lower part of the vacuum chamber.

The thermal evaporation source is usually coupled to the outside through a pipe and a wiring in order to control the process. Also, the thermal evaporation source is installed so as to be movable by a transfer apparatus in order to exchange and supply the organic thin film material. As a power source of the transfer apparatus, a step motor for vacuum is mainly used.

However, since the above-mentioned pipe and wiring are installed in the organic thin film forming apparatus having a high-vacuum environment on the order of about 10e-5 to 10e-8 Pa, they are rapidly aged and generate dust. Also, the occurrence of disconnection of the wiring in the vacuum chamber causes vacuum breaking and requires maintenance for a long time. Also, the step motor used in the transfer apparatus is difficult to use for monitoring a load factor under the high-vacuum environment, and deteriorates in driving force at the time of high-speed driving.

### SUMMARY OF THE INVENTION

It is an object of the present invention to provide a transfer apparatus and an organic deposition device with the capability of preventing leak occurrence in a vacuum chamber.

It is another object of the present invention to provide a transfer apparatus and an organic deposition device with the capability of minimizing fault generation by wiring and a pipe in a vacuum chamber.

It is yet another object of the present invention to provide transfer apparatus and an organic deposition device with the capability of minimizing the harmful effect on a vacuum chamber of disconnection and/or leak occurrence of wiring and a pipe in the vacuum chamber.

According to one aspect of the present invention, there is provided an organic deposition device including: a vacuum chamber; a stage installed in the vacuum chamber and having a substrate mounted thereon; a deposition source for evaporating an organic toward the substrate; a process utility line coupled to the deposition source and drawn out to the outside of the vacuum chamber; and a transfer apparatus for moving the deposition source in a direction parallel to the stage and having the process utility line installed therein.

Preferably, the interior of the transfer apparatus is maintained at atmospheric pressure.

The process utility line includes wiring for transmitting power and a signal to the deposition source, and a pipe for supplying cooling water thereto. Preferably, the wiring is a flexible wiring and the pipe is a flexible pipe.

The transfer apparatus includes: first and second arms; a first coupling part coupled to an interior of the vacuum chamber so as to form an inlet in which the process utility line is drawn and rotatably installed on one side of the first arm; a second coupling part rotatably coupling one side of the second arm to the other side of the first arm; and a third coupling part rotatably coupling the deposition source to the other side of the second arm.

The organic deposition device can further include a motor installed outside the vacuum chamber for supplying driving force to the transfer apparatus. The organic deposition device can further include a ball screw installed inside the vacuum chamber for converting the driving force of the motor from rotational movement into straight line movement.

The organic deposition device can further include a coupling box installed between the third coupling part and the deposition source. The organic deposition device can further include a pipeline installed between the coupling box and the deposition source.

The deposition source can be a point evaporation source or a linear evaporation source provided with an organic material.

According to another aspect of the present invention, there is provided a transfer apparatus used in an organic deposition device, including a deposition source for evaporating an organic toward a stage installed in a vacuum chamber, and a flexible process utility line coupled to the deposition source and drawn out to the outside of the vacuum chamber. The transfer apparatus includes: first and second arms; a first coupling part coupled to an inside of the vacuum chamber so as to form an inlet in which the process utility line is drawn and rotatably installed on one side of the first arm; a second coupling part rotatably coupling one side of the second arm to the other side of the first arm; and a third coupling part rotatably coupling the deposition source to the other side of the second arm. Herein, the process utility line is installed in the first coupling part, the first arm, the second coupling part, the second arm, and the third coupling part, and space in which the process utility line is installed is maintained at atmospheric pressure.

Preferably, the transfer apparatus further includes a motor installed outside the vacuum chamber for supplying driving force.

The transfer apparatus can further include a ball screw installed inside the vacuum chamber for converting rotational driving force of the motor into a straight line driving force.

With the present invention, the wiring and the pipe coupled to the deposition source are installed in the transfer apparatus, thereby making it possible to minimize fault generation by the wiring and the pipe in the vacuum chamber. Also, it is possible to prevent leak generation in the vacuum chamber. In addition, it is possible to minimize the harmful effect on the vacuum chamber of disconnection and/or leak generation of the wiring and the pipe in the vacuum chamber. Furthermore, the transfer apparatus in which the process utility line is installed is used, thereby making it is possible to improve stability and maintenance of the organic deposition device.

### BRIEF DESCRIPTION OF THE DRAWINGS

A more complete appreciation of the present invention, and many of the attendant advantages thereof, will be readily apparent as the present invention becomes better understood by reference to the following detailed description when considered in conjunction with the accompanying drawings in which like reference symbols indicate the same or similar components, wherein:

FIG. 1 is a configuration view for explaining a transfer apparatus and an organic deposition device according to a first embodiment of the present invention.

FIG. 2 is an operational state view for explaining the operational principles of key elements of the transfer apparatus of FIG. 1.

FIG. 3 is a configuration view for explaining a transfer apparatus and an organic deposition device according to a second embodiment of the present invention.

### DETAILED DESCRIPTION OF THE INVENTION

In the following detailed description, only certain exemplary embodiments of the present invention have been shown and described, simply by way of illustration. As those skilled in the art will realize, the described embodiments maybe modified in various ways, all without departing from the spirit or scope of the present invention. Accordingly, the drawings and description are to be regarded as illustrative in nature and not restrictive. In addition, when an element is referred to as being “on” another element, it can be directly on another element or be indirectly on another element with one or more intervening elements interposed therebetween. Also, when an element is referred to as being “connected to” another element, it can be directly connected to another element or be indirectly connected to another element with one or more intervening elements interposed therebetween. When a first element is described as being coupled to a second element, the first element may not only be directly coupled to the second element but also be indirectly coupled to the second element via a third element. Hereinafter, like reference numerals refer to like elements.

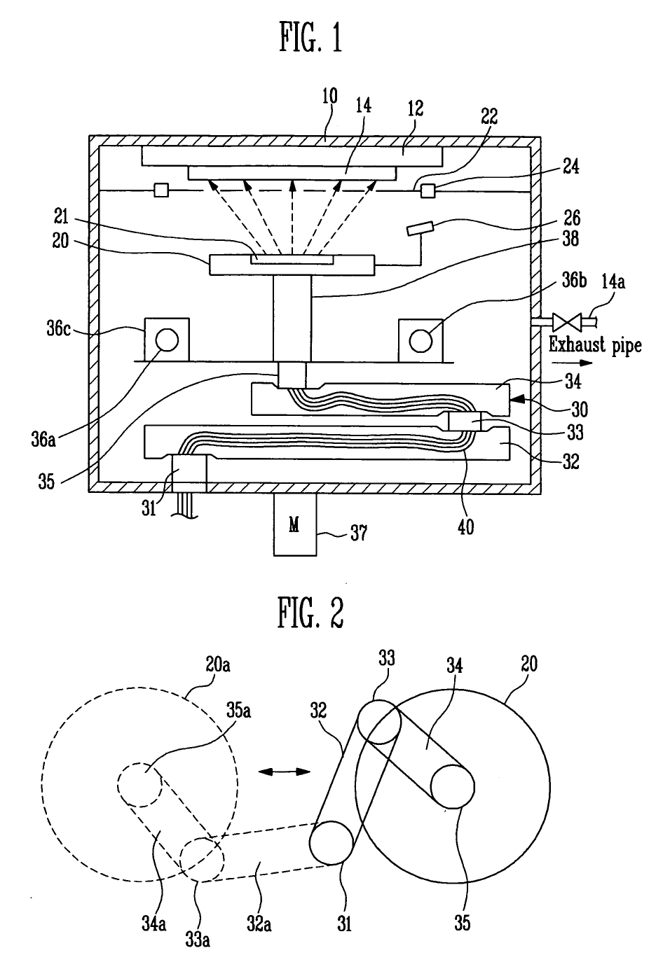

FIG. 1 is a configuration view for explaining a transfer apparatus and an organic deposition device according to a first embodiment of the present invention.

Referring to FIG. 1, the organic deposition device includes a vacuum chamber 10, a stage 12, a deposition source 20, a mask 22, a sensor 26, a transfer apparatus 30, and a process utility line 40. Also, the organic deposition device includes a vacuum exhaust system (not shown) for maintaining the vacuum chamber 10 a vacuum state, a power supply device (not shown) for supplying power to the vacuum chamber 10, and a control device (not shown) for controlling the process.

The vacuum chamber 10 has a predetermined internal space, and is installed to communicate with the vacuum exhaust system through an exhaust pipe 14a. The vacuum exhaust system may be constituted by a vacuum pump for exhausting a gas so that the gas does not remain in the internal space of the vacuum chamber 10. The internal space of the vacuum chamber 10 may be maintained in a constant vacuum state by the vacuum exhaust system. One side of the vacuum chamber 10 (for example, an upper side of the vacuum chamber 10) has the stage 12 installed thereon, and a substrate 14 is disposed on an upper part of the stage 12. The substrate 14 includes a glass substrate for fabricating an organic light emitting element.

The deposition source 20 includes a container which contains a material, such as an organic compound, or the like, a heat source for supplying heat to the container in order to evaporate the material, and a nozzle 21 for spraying the evaporated material toward the substrate 14. The materials discharged from the nozzle 21 of the deposition source 20 are deposited on a desired region of the substrate 14 through the mask 22. The mask 22, which is a shadow mask having a predetermined pattern, may be fixed inside the vacuum chamber 10 by a mask fixture 24. The vacuum chamber 10 may be provided with an aligner (not shown) in order to align the substrate 10 and the mask 22.

The evaporation speed of the material evaporated in the deposition source 20 is measured by a sensor 26 installed adjacent to the deposition source 20 inside the vacuum chamber 10. The sensor 26 may be provided as a thickness monitoring sensor. In this case, the sensor 26 measures the thickness of the material or the thickness of a film deposited on the substrate 14, and a controller (not shown) electrically coupled to the sensor 26 calculates the evaporation speed of the material, and controls the heat source or a cooling device coupled to the container so as to be able to control the evaporation speed of the material.

Also, the deposition source 20 is coupled to the transfer apparatus 30, and moves in a direction parallel to the substrate 14 seated on the stage 12 by means of the transfer apparatus 30. The sensor 26 may be coupled to the deposition source 20 in order to be able to move together with the deposition source 20.

The transfer apparatus 30 includes three coupling parts 31, 33, and 35 having a predetermined internal space, two arms 32 and 34, two ball screws 36a and 36b, and a motor 37. Each of the coupling parts 31, 33, and 35 is a vacuum coupling part, the outside of which is exposed to a vacuum environment, and the two ball screws 36a and 36b and the motor 37 form a driver of the transfer apparatus 30.

Each of the arms 32 and 34 has an internal space coupling between one end thereof and the other end thereof. The three coupling parts 31, 33, and 33 may be provided as a rotary feed-through capable of transmitting power and a signal to the inside under high-temperature and high-vacuum environments. The rotary feed-through is a device which includes a housing having a magnetic fluid or an elastic member installed therein in order to be sealed from the outside, and a rotary shaft installed in the housing so that wiring and a pipe therein can move together as the rotary shaft rotates. For example, the rotary feed-through includes a magnetic seal.

The transfer apparatus 30 according to the present embodiment is installed so as to supply and exchange the deposition source 20 for a deposition process, as well as, to be able to move the deposition source 20 while providing an independent atmospheric environment within the vacuum chamber 10 so that the process utility line 40 is not exposed to the vacuum environment.

More specifically, the first coupling part 31 is coupled to one end of the first arm 32, and the second coupling part 33 is coupled between the other end of the first arm 32 and one end of the second arm 34. The third coupling part 35 is coupled to the other end of the second arm 34. The three coupling parts 31, 33, and 35 are installed so as to be rotatable so that the process utility line 40, penetrating through the inside of the parts 31, 33 and 35, can move according to movement of the deposition source 20 in a state where they are coupled in line with the first arm 32 and/or the second arm 34.

The ball screws 36a and 36b convert rotational movement of the motor 37, installed outside the vacuum chamber 10, into straight line movement. The motor 37 in a stand-by state is coupled to the ball screws 36a and 36b through a gear at an end of a bracket 36c. A coupling box 38 is assembled as a single body with nuts of the right and left ball screws 36a and 36b, respectively, through a separate structure in the vacuum chamber 10 so as to perform the straight line movement. The third coupling part 35, located on a lower end of the coupling box 38, is coupled to the second arm 34 so as to perform the rotational movement. As such, the deposition source 20 performs the straight line movement by means of a driving force of the motor 37 and the ball screws 36a and 36b. In the present embodiment, the ball screws 36a and 36b are one embodiment of a device for converting the rotational movement of the motor 37 into the straight line movement, but may be replaced by another device for performing the same function.

The process utility line 40 includes wiring installed in order to transmit power and a control signal to the deposition source 20, wiring coupled to the sensor 26 which is coupled to the deposition source 20, and a pipe installed in order to provide a flow of cooling water to the deposition source 20. The wiring and the pipe maybe provided as a flexible cord and a flexible pipe, respectively.

One end of the process utility line 40 is coupled to the deposition source 20 and the sensor 26 through the coupling box 38. The coupling box 38 is an element by means of which wiring and a pipe of the deposition source 20, and wiring of the sensor 26 drawn out of the interior of the box, are coupled to one side of the process utility line 40. As such, the transfer apparatus 30 according to the present embodiment can include the coupling box 38 in order to easily couple the deposition source 20 and the installed process utility line 40.

The inside of the coupling box 38 may be maintained in a vacuum environment or an atmospheric environment. The insides of the first to third coupling parts 31, 33, and 35, and the first and second arms 32 and 34, are maintained in an atmospheric environment. Therefore, at least a portion of the process utility line 40 installed in the transfer apparatus 30 is protected without being exposed to the high-temperature and high-vacuum environments.

Meanwhile, although it has been described for convenience in the present embodiment that the motor 37 is coupled to the ball screws 36a and 36b on the lower side of the vacuum chamber 10, the motor 37 may be installed on the other side of the vacuum chamber 10 so as to be able to be easily coupled to the ball screws 36a and 36b.

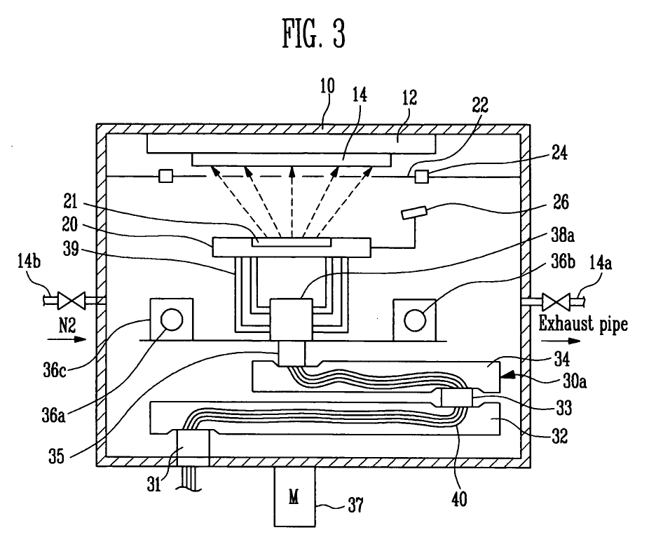

FIG. 2 is an operational state view for explaining the operational principles of key elements of the transfer apparatus of FIG. 1.

As shown in FIG. 2, the first arm 32 and the second arm 34 of the transfer apparatus 30 rotate according to the rotational movement of the first coupling part 31 fixed inside the vacuum chamber 10. Also, the second arm 34 rotates relative to the first arm 32 by means of the rotational movement of the second coupling part 33. The deposition source 20 and the coupling box 38, coupled to the second arm 34, rotate by means of the rotational movement of the third coupling part 35. At this point, when adjusting rotational angles of the first to third coupling parts 31, 33, and 35, the deposition source 20 coupled to the transfer apparatus 30 may move in a straight line direction. That is, the transfer apparatus 30 according to the present embodiment moves the deposition source 20 in the straight line direction by means of the driving force of the ball screws 36a and 36b coupled to the motor 37.

The rotational angles of the first to third coupling parts 31, 33, and 35 maybe adjusted by a guide member (not shown) for guiding a moving direction of the transfer apparatus 30 or the deposition source 20.

With the above-mentioned configuration, the transfer apparatus 30a which has been positioned at a first point moves in the straight line direction by a predetermined distance so as to be able to be positioned, like the transfer apparatus 30, at a second point. Herein, it is shown that the transfer apparatus 30a positioned at the first point includes the first coupling part 31, a first arm 32a, a second coupling part 33a, a second arm 34a, and a third coupling part 35a.

FIG. 3 is a configuration view for explaining a transfer apparatus and an organic deposition with the same according to a second embodiment of the present invention.

Referring to FIG. 3, the organic deposition device according to the second embodiment includes a vacuum chamber 10, a stage 12, a deposition source 20, a mask 22, a sensor 26, a transfer apparatus 30a, and a process utility line 40.

The transfer apparatus 30a according to the second embodiment includes three coupling parts 31, 33, and 35, two arms 32 and 34, two ball screws 36a and 36b, a motor 37, a coupling box 38a, and four pipelines 39. The process utility line 40 is installed in the three coupling parts 31, 33, 27 and 35, the two arms 32 and 34, the coupling box 38a, and the four pipelines 39.

In the second embodiment, the coupling box 38a is not directly coupled to the deposition source 20, but is coupled to the deposition source 20 through the pipelines 39. Each of the pipelines 39 is exposed to the vacuum chamber, and is fixedly installed between the coupling box 38a and the deposition source 20. Each of the pipelines 39 is installed with wiring for power or a control signal, a pipe for cooling water flow, or wiring coupled to the sensor 26.

An operational process of the organic deposition device according to the present embodiment will be schematically described below.

First, after putting a material for forming an organic light emitting element into a heating container of the deposition source 20, the gas inside the vacuum chamber is exhausted. When the vacuum chamber 10 arrives at a vacuum state capable of performing deposition, the deposition source 20 is heated. At this point, the deposition speed of the material is maintained at a desired speed by measuring the thickness of the material using the sensor 26. When the deposition speed is constantly maintained, the mask 22 and the substrate 14 are inserted through a gate valve and are aligned using an aligner (not shown). When the alignment is completed, a shutter (not shown) existing between the substrate 14 and the deposition source 20 is opened to perform a deposition process. When the thickness of a film deposited on the substrate 14 arrives at a desired thickness, the shutter is closed and the substrate is transferred to a next deposition chamber or a next process chamber.

A point deposition source for evaporating the deposition material at one point or a linear deposition source evaporating the deposition material at one line may be used as the deposition source 20 of the present embodiment. At this point, in order to maintain reproducivity of the deposition process, the deposition source 20 moves at a constant speed in a direction opposite to that of the substrate by means of the transfer apparatus 30a during the deposition process.

In the present embodiment, the process utility line 40 is installed in the transfer apparatus 30a having a shape similar to that of a robot arm, an interior of the transfer apparatus being maintained in an atmospheric environment. Therefore, the process utility line 40 may be effectively protected under high-temperature and high-vacuum environments of the vacuum chamber 10 during the deposition process. Also, since the process utility line 40 is installed in the transfer apparatus 30a, it has almost no effect on the interior of the vacuum chamber 10, even at the time of disconnection of the wiring or leak generation. In addition, since the motor 37 supplying driving force to the transfer apparatus 30a is installed in an atmospheric environment outside the vacuum chamber 10, maintenance of the motor 37 is easy.

The organic deposition device of the present invention may be implemented by an organic vapor phase deposition (OVPD) scheme using the transfer device. The OVPD scheme is a scheme in which an evaporated material is delivered to the substrate 14 by an inert gas such as nitrogen, and the delivered material is condensed above the cold substrate 14 so that the organic material is deposited on the substrate 14. In order to maintain the reproducivity of the deposition speed, the inert gas is accurately injected by a mass flow controller (MFC). The present method is substantially the same as the organic deposition device according to the present embodiment using the point deposition source or the linear deposition source as described above except for using the inert gas. In this case, the organic deposition device can include an inlet pipe 14b coupled to the vacuum chamber 10 in order to inject the inert gas, as shown in FIG. 3.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. An organic deposition device, comprising:
a vacuum chamber;
a stage installed in the vacuum chamber, and on which a substrate is mounted;
a deposition source for evaporating an organic toward the substrate;
a process utility line coupled to the deposition source and drawn out to an exterior of the vacuum chamber; and
a transfer apparatus for moving the deposition source in a direction parallel to the substrate, and having the process utility line installed therein.

2. The organic deposition device as recited in claim 1, wherein an interior of the transfer apparatus is maintained at atmospheric pressure.

3. The organic deposition device as recited in claim 1, wherein the process utility line comprises wiring for transmitting power and a signal to the deposition source, and a pipe for supplying cooling water thereto.

4. The organic deposition device as recited in claim 3; wherein the wiring is a flexible cord and the pipe is a flexible pipe.

5. The organic deposition device as recited in claim 1, wherein the transfer apparatus comprises:
first and second arms;
a first coupling part coupled to an interior of the vacuum chamber so as to form an inlet in which the process utility line is drawn and rotatably installed on one side of the first arm;
a second coupling part for rotatably coupling one side of the second arm to another side of the first arm; and
a third coupling part for rotatably coupling the deposition source to another side of the second arm.

6. The organic deposition device as recited in claim 5, further comprising a motor installed outside the vacuum chamber for supplying driving force to the transfer apparatus.

7. The organic deposition device as recited in claim 6, further comprising a ball screw installed inside the vacuum chamber for converting the driving force of the motor from rotational movement to straight line movement.

8. The organic deposition device as recited in claim 5, further comprising a coupling box installed between the third coupling part and the deposition source.

9. The organic deposition device as recited in claim 8, further comprising a pipeline installed between the coupling box and the deposition source.

10. The organic deposition device as recited in claim 1, wherein the deposition source is a point evaporation source or a linear evaporation source provided with an organic material.

11. A transfer apparatus used in an organic deposition device comprising a deposition source for evaporating an organic toward a stage installed in a vacuum chamber and a flexible process utility line coupled to the deposition source and drawn out to an exterior of the vacuum chamber, the transfer apparatus comprising:
first and second arms;
a first coupling part coupled to an interior of the vacuum chamber so as to form an inlet in which the process utility line is drawn, said first coupling part being rotatably installed on one side of the first arm;
a second coupling part for rotatably coupling one side of the second arm to another side of the first arm; and
a third coupling part for rotatably coupling the deposition source to another side of the second arm;
wherein the process utility line is installed in the first coupling part, the first arm, the second coupling part, the second arm, and the third coupling part, and a space in which the process utility line is installed is maintained at atmospheric pressure.

12. The transfer apparatus as recited in claim 11, wherein the process utility line comprises wiring for transmitting power and a signal to the deposition source, and a pipe for supplying cooling water thereto.

13. The transfer apparatus as recited in claim 11, further comprising a motor installed outside the vacuum chamber for supplying driving force.

14. The transfer apparatus as recited in claim 13, further comprising a ball screw installed inside the vacuum chamber for converting rotational driving force of the motor to straight line driving force.
